(19) United States
(12) Patent Application Publication
(10) Pub. No.: US 2003/0218468 A1
(43) Pub. Date: Nov. 27, 2003

(54) Apparatus and method for measuring characteristics of anisotropic materials

(76) Inventor: Wayne Stephen Holmes, Auckland (NZ)

Correspondence Address: Diane L. Gardner, Fish & Richardson P.C., Suite 500, 4350 La Jolla Village Drive, San Diego, CA, 92121, US

(21) Appl. No.: 10/369,266

(22) Filed: Feb. 14, 2003

Related U.S. Application Data
(63) Continuation of application No. PCT/NZ01/00165, filed on Aug. 15, 2001.

(30) Foreign Application Priority Data
Aug. 15, 2000 (NZ) 506359

(51) Int. Cl. G01R 27/04; G01R 27/32

(52) U.S. Cl. 324/637

(57) ABSTRACT

Apparatus (1) for determining material characteristics of an object (2) is provided, the apparatus including at least one microwave sensing system including generating means 3 and transmitting means (4) for generating and transmitting one or more microwave signals on to one or more focal points located substantially on the surface of an object to be measured. The energy or power of microwave signals reflected from the object (2) is detected and at least one measurement value is computed dependent on the reflected microwave signals, wherein the measurement value is indicative of one or more material characteristics of the object. Also provided is a method of determining material characteristics of an object including focussing microwave energy onto the surface of the object and detecting the reflected signals. The apparatus and method may be used to provide a measure of the length of the object and the location of characteristics of the object along its length.

### TECHNICAL FIELD

This invention relates to an apparatus and method for measuring material characteristics of anisotropic materials and in particular, but not exclusively to an apparatus and method for detecting characteristics of an anisotropic material having a curved surface, more particularly, logs.

### BACKGROUND ART

Objects illuminated by microwave signals may reflect, absorb or transmit differing amounts of the signals depending on the material characteristics of the object. These differences may be used to detect variations in material characteristics within a single object or between objects. In the context of a wooden plank, defects in the plank may be located and analysed from the results of measured reflected, transmitted or otherwise refracted microwave energy from that portion of the plank. Variations in the measurements may be caused by changes in the grain direction or variations in the moisture content in different locations along the plank.

One known method of using microwave signals to analyse material characteristics of an object involves transmitting microwave signals through the object and detecting the signals that have been transmitted to the opposite side of the object, see the specification of U.S. Pat. No. 4,514,680. This method is problematic when attempting to detect particular characteristics of logs. The relatively large diameter of the log (in comparison, for example, to wooden planks) means that microwave signals transmitted through the log may pass through wood having a number of different properties along the transmission path. The accumulative effect of these variations results in difficulties to identify and measure specific characteristics of the log in isolation. The measurement of properties of branch stems is one example where variations in material adjacent to the branch stem may adversely affect accurate measurement of the properties of the branch stem.

Furthermore, known methods of utilising microwave signals for object evaluation typically involve applying a microwave signal over the entire width of the object. For a generally cylindrical-shaped log, the curved surface in combination with the varying thickness of material across the log causes inaccuracies in measurement. Also, the surface of a typical log is not uniform, causing further variation in the reflected and refracted signals. Therefore, present methods involving the use of microwave signals, while useful for detection of variations in materials are often ineffective for accurately measuring properties of the variations.

The use of optical signals, for example lasers, have met with varying success in the detection of branch stems. Typically, in woods other than radiata pine, which typically swells in areas of branch-stems, the use of laser detection is unreliable. Furthermore, optical signals only provide information on the presence or absence of branch stems and provides little or no reliable information as to the direction or extent the branch stem extends into the log. This information may be required in order to identify the optimum cutting locations for the log.

Thus, it is an object of the present invention to provide a method and apparatus for detecting characteristics of anisotropic materials that alleviate or overcome problems in branch stem detection at present, or at least to provide the public with a useful choice.

Further objects of the present invention may become apparent from the following description.

Any discussion of the prior art throughout the specification should in no way be considered as an admission that such prior art is widely known or forms part of common general knowledge in the field.

### DISCLOSURE OF THE INVENTION

According to one aspect of the present invention, there is provided apparatus for determining material characteristics of an object, the apparatus including:

at least one microwave sensing system including microwave signal generation and transmission means to generate and transmit one or more microwave signals on to one or more focal points located substantially on the surface of an object to be measured and microwave signal detection means for detecting the energy or power of microwave signals reflected from the object; and

computing means for computing at least one measurement value dependent on microwave signals detected by the microwave sensing system, wherein the measurement value is indicative of one or more material characteristics of the object.

Preferably, the apparatus may include a control means to control the microwave sensing system to compute a plurality of measurement values over the surface area of the object, thereby creating an image of the object.

Preferably, the apparatus may compare the measurement value or values with a predetermined object model to identify measurement values that indicate particular characteristics of the object.

Preferably, the at least one microwave sensing system may generate, transmit and detect microwave signals of variable frequency over a predetermined frequency range and the computing means may compute a measurement value dependent on the detected microwave signals over said predetermined frequency range.

Preferably, the at least one microwave sensing system may generate and transmit a discrete number of frequencies within said frequency range.

Preferably, the microwave sensing system may include an array of microwave sensors arranged and operated to obtain a two dimensional image of the object.

Preferably, the microwave sensing system may scan the focal point over the surface of the object to obtain the two-dimensional image of the object.

Preferably, the microwave transmission means may transmit microwave signals at a pre-selected angle relative to the surface of the object, the pre-selected angle selected to maximise variation of the measurement value in response to variation of a particular characteristic of the object.

Preferably, the object may be a log and the material characteristics may include the presence or absence of a branch stem.

Preferably, the predetermined angle may be selected so as to direct the microwave signals generally towards the base of a log.

Preferably, the apparatus may compute an angle of projection of a branch stem into a log dependent on the magnitude of the measurement value and using prior knowledge of a relationship between angle of projection and magnitude of the measurement value.

Preferably, the apparatus may compute the area a branch stem occupies on or near the surface of a log from predetermined variations in the measurement value.

Preferably, the apparatus may compute the extent of projection of a branch-stem into a log dependent on the computed area and based on prior knowledge of a relationship between the extent of projection and the area a branch stem occupies on or near the surface of a log.

Preferably, the computing means may compute the angle and extent that a branch stem extends into a log from a predetermined model of branch stems, using the measurement value and surface area of the branch stem as input variables to the model.

According to another aspect of the present invention, there is provided a method of determining material characteristics of an object, the method including transmitting at least one microwave signal onto at least one focal point located substantially on the surface of the object, detecting the power or energy of microwave signals reflected from the object for the or each focal point and determining at least one measurement value indicative of the detected power or energy, wherein the magnitude of the measurement value is indicative of one or more material characteristics of the object.

Preferably, the method may include determining a plurality of measurement values over the surface area of the object, thereby creating an image of the object.

Preferably, the method may include comparing the measurement value or values with a predetermined object model to indicate the one or more material characteristics.

Preferably, the method may include generating and transmitting microwave signals of variable frequency over a predetermined frequency range and computing the or each measurement value dependent on detected reflected microwave signals over said frequency range.

Preferably, the object may be a log and the method may include directing the microwave signals generally towards the base of the log.

Preferably, the method may include determining the angle of projection of a branch stem into a log dependent on the magnitude of the measurement value or values and using prior knowledge of a relationship between the angle of projection and the magnitude of the measurement value or values.

Preferably, the method may include computing the area a branch stem occupies on or near the surface of a log and determining the extent of projection of a branch-stem into a log dependent on the computed area.

Preferably, the method may include computing the angle and extent which a branch stem extends into a log from a predetermined model of branch stems, using the magnitude of the measurement value or values and the surface area of the branch stem as input variables for the computation.

According to another aspect of the present invention, there is provided apparatus for determining material characteristics of an object, the apparatus including:

at least one microwave sensing system including microwave signal generation and transmission means to generate and transmit one or more microwave signals on to a plurality of focal points located substantially on the surface of an object to be measured and microwave signal detection means for detecting the energy or power of microwave signals reflected from the object;

computing means for computing a measurement value dependent on microwave signals detected by the microwave sensing system;

control means for controlling the sensing system to capture at least two two-dimensional images of the object, the images formed by a plurality of measurement values and captured a pre-selected time from each other;

wherein the apparatus is adapted to cause the computing means to determine the spatial displacement of the at least two images of the object and compute the speed of the object past the sensors in at least one direction from the spatial displacement and the pre-selected time.

Preferably, the apparatus may detect the passing of a leading and trailing edge of the object past at least one of the microwave sensing systems and determine the time difference between detection of the leading and trailing edges, wherein the computing means computes the length of the object from the time difference and the computed speed of the object.

Preferably, the apparatus may identify the location of at least one material characteristic of the object dependent on the detection of predetermined variations in the measured value and identification of the leading and trailing edge of the object.

Preferably, the apparatus may form part of a processing line, wherein further processing is dependent on the location of the at least one material characteristic.

Preferably, the object may be a log and the material characteristic may include the presence of a branch stem.

According to another aspect of the present invention, there is provided a method of determining material characteristics of an object, the method including capturing two two-dimensional images of the object by:

a) transmitting at least one microwave signal onto a focal point located substantially on the surface of the object and detecting the power or energy of microwave signals reflected from the object;

b) determining a measurement value indicative of the detected power or energy;

c) obtaining a plurality of measurement values over the image area; and

d) repeating steps a) through c) to capture a second image a preselected time duration after capturing a first image; and

determining the spatial displacement of the at least two images of the object and computing the speed of the object past the sensors in at least one direction from the spatial displacement and the pre-selected time.

Preferably, the method may further include detecting the passing of a leading and trailing edge of the object, determining the time difference between detection of the leading and trailing edges and computing the length of the object from the time difference and the computed speed of the object.

Preferably, the method may further include identifying the location of at least one material characteristic of the object dependent on the detection of predetermined variations in the measured value and identification of the leading and trailing edge of the object.

Further aspects of the present invention, which should be considered in all its novel aspects, may become apparent from the following description, given by way of example only and with reference to the accompanying drawings.

### BRIEF DESCRIPTION OF DRAWINGS

FIG. 1: shows a schematic representation of an apparatus according to one embodiment of the present invention in use, measuring the material characteristics of a log.

FIG. 2: shows an example of expected typical measurements from a log.

FIG. 3: shows a schematic representation of an array of sensors in accordance with another embodiment of the present invention.

### MODES FOR CARRYING OUT THE INVENTION

Although the following description is given in relation to use of the present invention for the detection branch-stems in logs, it will be appreciated by those skilled in the relevant arts that the apparatus and method may be applicable to a variety of different objects exhibiting anisotropic or other varying characteristics to microwave signals and to detect a variety of different characteristics. However, the present invention is anticipated to have particular application to measuring characteristics of objects which are anisotropic for the reflection of microwave signals and which have a curved or variable surface.

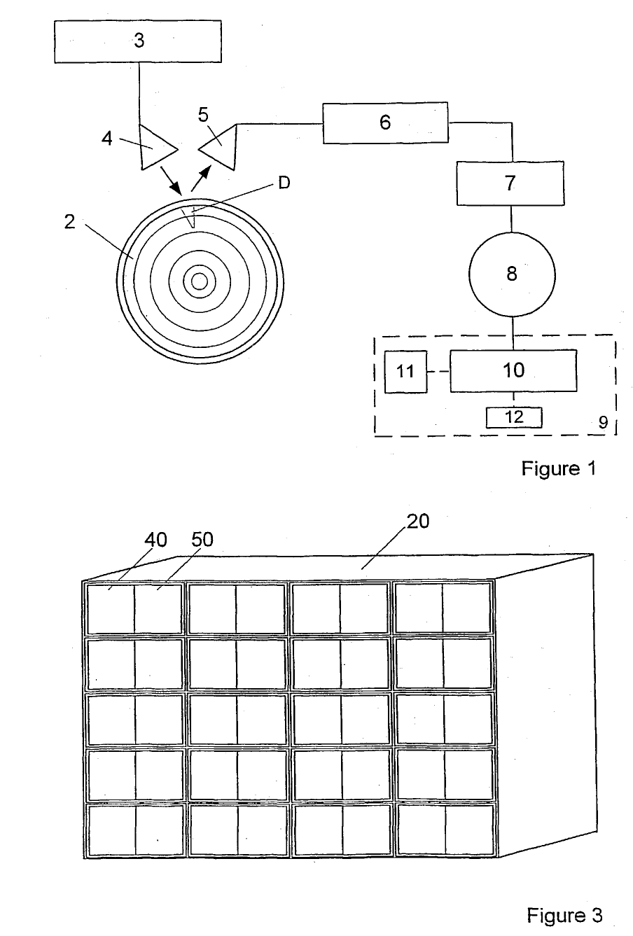

Referring first to FIG. 1, a block diagram representation of the transmitting and receiving portions of an apparatus 1 according to the present invention is shown, transmitting microwave signals onto the surface of a log 2. The log 2 in FIG. 1 is travelling into the page while the microwave signals are being applied thereto.

The apparatus 1 includes a microwave signal generating means 3 suitable for producing microwave signals of at least one frequency. For example, the microwave generating means 3 may generate one or more signals in the X-band. Preferably, the microwave generating means 3 may be capable of generating microwave signals at least at predetermined steps over a range of microwave frequencies, for example between 8.2 to 12.4 GHz in 101 steps. It will be appreciated by those skilled in the art that variations in the frequency range and number of steps may be made depending on the specific requirements of the apparatus 1. In the limits, the frequency may constantly ramp upwards (or downwards) or only a single frequency signal may be generated.

The microwave generating means 3, which may be a sweep oscillator feeds the microwave signals to a transmitting antenna 4. The microwave generating means 3 may be controlled to generate and transmit microwave signals on command or automatically at predetermined time periods. The transmitting antenna 4 is may be a horn antenna. However, any other microwave generation and transmission means suitable for transmitting focussed microwave energy may alternatively be used, including a guide structure having a coupling antenna. The transmitting antenna 4 focuses the transmitted microwave signals substantially onto the surface of the log 2.

A receiving antenna 5 is positioned to detect reflected microwave signals from the log 2, thereby creating an image of the log 2. The receiving antenna 5 may be a horn antenna, however, as with the transmitting antenna 4, a number of alternatives may be used. The signal received by the receiving antenna 5 is detected by a diode detector 6, which outputs a DC voltage indicative the energy of the microwave signals received. This voltage is then converted to a digital value by an analogue to digital converter 7. The value for each step of the frequency range may then be summed by suitable hardware or software represented by circle 8, to obtain an average value which is representative of the reflectance of the portion of the log 2 to which the microwave signals have been applied. The sum function may be replaced by an integrating function if a microwave signal with ramped frequency variation is used. This information is then output to an output device 9. The output device 9 may, for example, be a display, recorder, or processor for further processing depending on the required use of the information from the apparatus 1.

The output device 9 may be a computer processor including a communication interface 10 for receiving the summed detected values over the frequency range, a processing means 11 with associated memory 12 and a display 13. Optionally, one or both of the summing function and analogue to digital conversion may be performed by the output device 9. A computer processor provided in or in communication with the output device 9 may also control the microwave generating means 3.

A network analyser operating in a 2 port transmission measurement mode may be used as a substitute for the separate components described above. However, cost considerations may dictate that a dedicated processing system is used incorporating the detection and processing capabilities detailed above with reference to FIG. 1.

To simplify the analysis, the transmitted microwave signals may be constant between image captures. This avoids having to include characteristics of the transmitted signal in each computation on each image capture.

The apparatus 1 may scan the microwave signals across the log 2 as it travels past the transmitting antenna 4 and receiving antenna 5 so as to obtain measurements across the width and along the length of the log. A mechanical or electrical scanning system may be used for this purpose as is known in the art. Multiple transmitters may be provided, or the log and transmitter rotated relative to each other in order to provide measurements on all surfaces of the log 2.

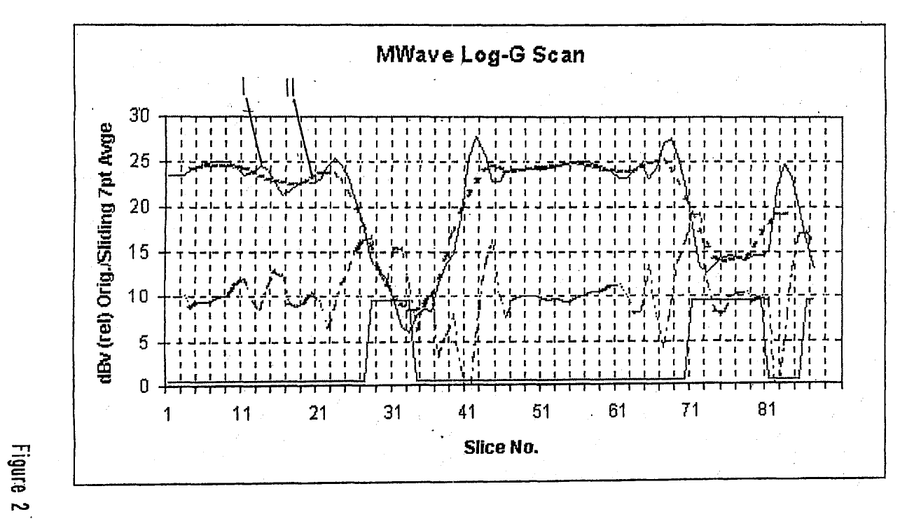

In order to increase the reliability of the measurements, the reflectance of each point on the log 2 may be measured for a plurality of frequencies. The power or energy of the reflected microwave signals are then summed or integrated over the frequency range to obtain a measurement of the power spectral density of the reflected signals. An example of a typical plot of the power spectral density measurement from a log 2 is shown in FIG. 2.

FIG. 2 shows a plot of the power spectral density of the reflected signals across 87 slices of a log 2. The original measurements are indicated by plot 1, which have been averaged using a sliding seven point average as indicated by plot 11. As wood is an anisotropic media for the reflection of microwave signals, the energy reflected is dependent upon the grain angle. Reflectance is also influenced by the moisture content of the log 2. As the grain direction of branch stems tends to be oriented more transverse to the longitudinal axis than in other areas of the log 2, the power or energy of the reflected microwave signals tends to be reduced. Also, the moisture content of branch stems tends to be higher than other parts of the logs, causing a further attenuation of the reflected signals. Therefore, from the plots shown in FIG. 2, branch stems are shown to be present at slice 32 and at slice 74.

Having prior knowledge of the reflectance of logs at the location of branch stems allows the processing means 11 to determine the presence of branch stems. Information defining a threshold may be stored within the memory 12, wherein measured reflectance values less than the threshold indicate a branch stem. Alternatively, or in addition, a threshold change and/or rate of change in the energy or power of the microwave signals may indicate a branch stem.

The plotted points in FIG. 2 may each represent an average value of a plurality of measurement values obtained from a plurality of focal points on or near the surface of the log 2. For example, a plurality of focal points extending across the log may be averaged. Alternatively, each measurement value used for subsequent analysis may be derived from a singe focal point.

It will be appreciated by those skilled in the art that if other characteristics of the log or characteristics of another object are to be detected, then the criteria used to evaluate the reflectance value may differ. The processing means 11 may transform the reflectance value to obtain a measurement value on a particular scale or using particular units of measure if required.

The movement of the log 2 past the apparatus 1 or vice-versa may be controlled to allow identification of where along the log 2 each slice has been taken. For example, each slice may be located along the log 2 at intervals of 1 cm. Alternatively, measurements of the velocity of the log 2 past the apparatus 1 may be measured (see later herein).

The branch stem at slice 32 has reflected significantly less microwave energy than the branch stem of slice 74. The amount of attenuation may be related to the extent to which the direction of the grains of the wood in the branch stem are parallel to the angle of transmission of the microwave signals. The moisture and density of the log may be assumed constant to simplify the analysis if required. Therefore, the angle of projection of the branch stem into the interior of the log 2 may be determined having knowledge of the angle of transmission of the microwave signals onto the surface of the log 2 and the extent of attenuation of the reflected signals.

As the microwave signals are focussed on the surface of the log, reflections from any irregularities of the log below the surface contribute a reduced part to the received reflected signal. Additional filtering of the signal may further reduce the contribution of the detected signal by subterranean reflections.

For branch stem detection in logs, the microwave signals are preferably transmitted at a predetermined angle relative to the longitudinal axis of the log so that the signals are directed generally towards the base of the log (base of the tree before felling). The predetermined angle may be the average expected angle of the wood grains forming branch stems into the log 2.

Using apparatus with a single microwave source and single sweep may result in multiple potential angles of projection. However, the most likely angle of projection may be determined from known characteristics of the log 2, for example by orienting the log 2 so that it is known which direction was the top of the log.

The size of the branch stem on the surface of the log 2 may be measured by detecting the number of slices across which the signal is attenuated by a predetermined threshold. A similar measurement may be taken for each scan across the log 2 to obtain the width of the branch stem on the surface of the log 2. Having knowledge of the measured area of the branch stem on the surface of the log 2 and the angle of projection of the branch stem, or more particularly the angle of projection of the wood grains forming the branch stem, the extent to which the branch stem extends into the interior of the log may be estimated according to a model of the expected projections given one or more preferably both of the aforementioned variables. Therefore, the log 2 may be processed according to this estimation in order to maximise the available yield from the log 2.

Referring to FIG. 3, a representation of an array 20 of microwave transmitter and receiver pairs, one of transmitters denoted by reference numeral 40 and one of the receivers by reference numeral 50. With such an array of sensors, a two-dimensional reflectivity profile may be obtained quickly. This may avoid or reduce the requirement for physically scanning of the sensors over the surface of the log. The sensor and receiver pairs may optionally be oriented and located to complement the average surface shape of the log so that the microwave signals generally contact the surface of the log at substantially the same angle on average. To avoid cross-coupling problems, each sensor may be independently activated and read sequentially, in which case the focal point is effectively scanned across the log.

The array 20 may also be used for measuring the speed of movement and length of the log. Two successive images of the log are taken at a predetermined time separation. A cross correlation between the images is then performed to establish the displacement of the log between image captures. The displacement and time information immediately provide the speed of the log. As the image has two dimensions, the speed of the log in two orthogonal dimensions may be computed if required. The apparatus then needs only determine the time between when the leading and trailing edges of a log are detected. This information, together with the speed of the log provides the required information to determine the log length. If a plurality of measurements of speed are taken, these may be averaged.

The two dimensional image of the log may alternatively be obtained by scanning fewer sensors over the log surface. However, a penalty of slower image capture may result.

In a first embodiment, the log length may be computed by performing an image cross correlation through the following steps. First the two images, each matrix of J×K pixels are captured by the array 20 and corresponding rest of the apparatus 1. The dc component is removed and the resulting ac values over each image are inserted into a 2J×2K matrix, with the corners of each image matrix located at the corners of the larger 2J×2K matrix. The remainder of the 2J×2K matrix entries are zeroed.

Next, the two-dimensional fast-Fourier transform (FFT) of each 2J×2K matrix is computed and one result is multiplied with the complex conjugate of the other. This results in the cross-spectrum of the two images. This cross-spectrum is then high-pass filtered through multiplication with a suitable kernel for high-pass filtering.

Finally, the point of maximum brightness is identified within the high-pass filtered image signal. From this, the displacement of the two images is identified by the distance the point of maximum brightness is from the centre of the image.

In an alternative embodiment, which may be preferred when speed of processing is important, the displacement may be computed using sequential registration. For a given candidate shift of [m,n] of image I₂ from image I₁, each represented by a j×k matrix, the error E in equation 1 is accumulated for pixel values in a window area defined by the limits of j and k. If the error exceeds a predetermined threshold value before all j×k points in the window area have been visited, it is assumed that the test has already failed for that particular window and a new window is tested. At the end of this process, the window with the lowest average error is assumed to define the registration point.

$$E = {\sum }_{j} {\sum }_{k} abs [ {I}_{1} ( j , k ) - {I}_{2} ( j - m , k - n ) ] \qquad Equation 1$$

While in the foregoing description, the preferred form of the invention of obtaining a two-dimensional image of the log has been described, a single dimension may be sufficient if it is known that the log only travels in one direction. Alternatively, a three dimensional image may be required if the log (or other object) may be moving along three axes relative to the angle of propagation of the microwave signals from the sensors.

The distance of the registration point from the centre of image I₁ represents the displacement of image I₂ from image I₁. The length of the log follows from the displacement information and the time between capturing of images I₁ and I₂.

The methods of determining the length of the log using cross-correlation of images or sequential registration may be used in addition to as an alternative to the method described previously herein of counting the number of slices when the log is present below the sensors. With information available regarding the length of the log, location of branch stems and an estimation of their three-dimensional size, accurate processing of the logs may be achieved that seeks to maximise the timber yield from each log.

Although the above description refers to analysing the microwave signals in one dimension (see FIG. 2 and the accompanying description), the analysis is more preferably performed in two dimensions. This obtains a more accurate measurement of the area a branch stem occupies and more information regarding the direction of the grains within the area occupied by the branch stem. The penalty is increased complexity in the processing requirements.

Where in the foregoing description reference has been made to specific components or integers of the invention having known equivalents then such equivalents are herein incorporated as if individually set forth.

Although this invention has been described by way of example and with reference to possible embodiments thereof, it is to be understood that modifications or improvements may be made thereto without departing from the scope of the appended claims.

1. Apparatus for determining material characteristics of an object, the apparatus including:
at least one microwave sensing system including microwave signal generation and transmission means to generate and transmit one or more microwave signals on to one or more focal points located substantially on the surface of an object to be measured and microwave signal detection means for detecting the energy or power of microwave signals reflected from the object; and
computing means for computing at least one measurement value dependent on microwave signals detected by the microwave sensing system, wherein the measurement value is indicative of one or more material characteristics of the object.

2. The apparatus of claim 1, including control means to control the microwave sensing system to compute a plurality of measurement values over the surface area of the object, thereby creating an image of the object.

3. The apparatus of either claim 1 or claim 2, wherein the processing means compares the measurement value with a predetermined object model to identify measurement values that indicate particular characteristics of the object.

4. The apparatus of any one of claims 1 to 3, wherein the at least one microwave sensing system generates, transmits and detects microwave signals of variable frequency over a predetermined frequency range and the computing means computes a measurement value dependent on the detected microwave signals over said predetermined frequency range.

5. The apparatus of claim 4, wherein the at least one microwave sensing system generates and transmits a discrete number of frequencies within said frequency range.

6. The apparatus of any one of the preceding claims, wherein the microwave sensing system includes an array of microwave sensors arranged and operated to obtain a two dimensional image of the object.

7. The apparatus of any one of the preceding claims, wherein the microwave sensing system scans the focal point over the surface of the object to obtain the two-dimensional image of the object.

8. The apparatus of any one of the preceding claims, wherein the microwave transmission means transmits microwave signals at a pre-selected angle relative to the surface of the object, the pre-selected angle selected to maximise variation of the measurement value in response to variation of a particular characteristic of the object.

9. The apparatus of any one of the preceding claims, wherein the object is a log and the material characteristics includes the presence or absence of a branch stem.

10. The apparatus of claim 9, wherein the predetermined angle is selected so as to direct the microwave signals generally towards the base of a log.

11. The apparatus of either claim 9 or claim 10, wherein the apparatus computes an angle of projection of a branch stem into a log dependent on the magnitude of the measurement value and using prior knowledge of a relationship between angle of projection and magnitude of the measurement value.

12. The apparatus of any one of claims 9 to 11, wherein the apparatus computes the area a branch stem occupies on or near the surface of a log from predetermined variations in the measurement value.

13. The apparatus of claim 12, wherein the apparatus computes the extent of projection of a branch-stem into a log dependent on the computed area and based on prior knowledge of a relationship between the extent of projection and the area a branch stem occupies on or near the surface of a log.

14. The apparatus of claim 12, wherein the computing means computes the angle and extent that a branch stem extends into a log from a predetermined model of branch stems, using the measurement value and surface area of the branch stem as input variables to the model.

15. A method of determining material characteristics of an object, the method including transmitting at least one microwave signal onto at least one focal point located substantially on the surface of the object, detecting the power or energy of microwave signals reflected from the object for the or each focal point and determining at least one measurement value indicative of the detected power or energy, wherein the magnitude of the measurement value is indicative of one or more material characteristics of the object.

16. The method of claim 15, further including determining a plurality of measurement values over the surface area of the object, thereby creating an image of the object.

17. The method of either claim 15 or claim 16, further including comparing the measurement value or values with a predetermined object model to indicate the one or more material characteristics.

18. The method of any one of claims 15 to 17, further including generating and transmitting microwave signals of variable frequency over a predetermined frequency range and computing the or each measurement value dependent on detected reflected microwave signals over said frequency range.

19. The method of any one of claims 15 to 18, wherein the object is a log and the method includes directing the microwave signals generally towards the base of the log.

20. The method of claim 19, including determining the angle of projection of a branch stem into a log dependent on the magnitude of the measurement value or values and using prior knowledge of a relationship between the angle of projection and the magnitude of the measurement value or values.

21. The method of either claim 19 or claim 20, further including computing the area a branch stem occupies on or near the surface of a log and determining the extent of projection of a branch-stem into a log dependent on the computed area.

22. The method of claim 20, further including computing the angle and extent which a branch stem extends into a log from a predetermined model of branch stems, using the magnitude of the measurement value or values and the surface area of the branch stem as input variables for the computation.

23. Apparatus for determining material characteristics of an object, the apparatus including:
at least one microwave sensing system including microwave signal generation and transmission means to generate and transmit one or more microwave signals on to a plurality of focal points located substantially on the surface of an object to be measured and microwave signal detection means for detecting the energy or power of microwave signals reflected from the object;
computing means for computing a measurement value dependent on microwave signals detected by the microwave sensing system;
control means for controlling the sensing system to capture at least two two-dimensional images of the object, the images formed by a plurality of measurement values and captured a pre-selected time from each other;
wherein the apparatus is adapted to cause the computing means to determine the spatial displacement of the at least two images of the object and compute the speed of the object past the sensors in at least one direction from the spatial displacement and the pre-selected time.

24. The apparatus of claim 23, adapted to detect from the measurement values the passing of a leading and trailing edge of the object past at least one of the microwave sensing systems and determine the time difference between detection of the leading and trailing edges, wherein the computing means computes the length of the object from the time difference and the computed speed of the object.

25. The apparatus of claim 24, adapted to identify the location on the object of at least one material characteristic of the object dependent on the detection of predetermined variations in the measured value and identification of the leading and trailing edge of the object.

26. The apparatus of claim 25, wherein the apparatus forms part of a processing line, wherein further processing is dependent on the location of the at least one material characteristic.

27. The apparatus of either claim 25 or claim 26, wherein the object is a log and the material characteristic includes the presence of a branch stem.

28. A method of determining material characteristics of an object, the method including capturing two two-dimensional images of the object by:
transmitting at least one microwave signal onto a focal point located substantially on the surface of the object and detecting the power or energy of microwave signals reflected from the object;
determining a measurement value indicative of the detected power or energy;
obtaining a plurality of measurement values over the image area; and
repeating steps a) through c) to capture a second image a preselected time duration after capturing a first image;
and wherein the method further includes:
determining the spatial displacement of the at least two images of the object and computing the speed of the object past the sensors in at least one direction from the spatial displacement and the pre-selected time.

29. The method of claim 28, further including detecting the passing of a leading and trailing edge of the object, determining the time difference between detection of the leading and trailing edges and computing the length of the object from the time difference and the computed speed of the object.

30. The method of either claim 28 or claim 29, further including identifying the location of at least one material characteristic of the object dependent on the detection of predetermined variations in the measured value and identification of the leading and trailing edge of the object.

31. Apparatus for detecting the material characteristics of an object substantially as herein described with reference to FIGS. 1 and 2 or FIG. 3.

32. A method of detecting the material characteristics of an object substantially as herein described with reference to FIGS. 1 and 2 or FIG. 3.
